(19) United States
(12) Patent Application Publication
(10) Pub. No.: US 2005/0082589 A1
(43) Pub. Date: Apr. 21, 2005

(54) Semiconductor device and manufacturing method of the same

(76) Inventors: Takafumi Noda, Shiojiri-shi (JP); Yoshinobu Yusa, Sakata-shi (JP); Kazunobu Kuwazawa, Chino-Shi (JP)

Correspondence Address: EDWARDS & ANGELL, LLP, P.O. Box 55874, Boston, MA, 02205, US

(21) Appl. No.: 10/932,440

(22) Filed: Sep. 2, 2004

(30) Foreign Application Priority Data
Sep. 3, 2003 (JP) 2003-311405

(51) Int. Cl. H01L 27/108

(52) U.S. Cl. 257/300

(57) ABSTRACT

A first conductive layer, a dielectric layer and a second conductive layer are continuously deposited, the second conductive layer is patterned and the upper electrode 13a of the MIM capacitor C is formed, and subsequently, a protective layer is deposited on the entire face. Next, the protective layer is patterned, and at the same time, the dielectric layer is also patterned with the same mask and the capacitive insulation layer 12a of the MIM capacitor is formed. Next, using the protective layer as a hard mask, the first conductive layer is patterned, and the lower electrode 11a and the wiring 11b of the MIM capacitor are formed. Because the MIM capacitor C is formed as the above, the outer circumferential shape of the lower electrode 11a is generally the same as that of the capacitive insulation layer 12a.

### FIELD OF THE INVENTION

The present invention relates to a semiconductor device having a capacitive element and a manufacturing method of the same.

### BACKGROUND

Conventionally, a MIM (Metal-Insulator-Metal) capacitor having a small parasitic capacitance has been used as one of capacitive elements formed in a semiconductor device (for example, Japanese Unexamined Patent Publication No. H8-306862 (Patent Document 1), and Japanese Unexamined Patent Publication No. 2002-141472 (Patent Document 2).

The MIM capacitor is formed by a lower electrode formed by a first conductive layer, an upper electrode formed by a second conductive layer and capacitive insulation layer sandwiched therebetween and formed by a dielectric layer. The first conductive layer is deposited on an insulation layer formed on a semiconductor substrate, and later formed on the lower electrode by being patterned by etching or the like. The dielectric layer is deposited on the lower electrode or on the first conductive layer before patterning, and later formed on the capacitive insulation layer by etching or the like. Further, the second conductive layer is deposited on the dielectric layer, and later formed on the upper electrode by patterning by etching or the like.

However, in the conventional MIM capacitor described in the Patent Document 1, before the dielectric layer is deposited, the lower electrode is formed by etching the first conductive layer. As a result, due to the effect of etching, smoothness on the face of the lower electrode is impaired, and the face is contaminated, and therefore it has a problem that an insulation withstand voltage of the capacitive element is reduced.

Further, in the conventional MIM capacitor described in the Patent Document 2, after the first conductive layer, the dielectric layer and the second conductive layer are continuously deposited, each of them is etched, and the lower electrode, the capacitive insulation layer and the upper electrode are formed. However, because the upper electrode and the capacitive insulation layer are formed in the same shape by etching, the edges of the capacitive insulation layer are damaged by the etching, and then there is the problem that the insulation withstand voltage is reduced. Here, the damage caused by etching means includes defects and contamination or the like.

This invention has been achieved under consideration of the above problems, and the objective is to provide a semiconductor device suppressing reduction in the insulation withstand voltage of the capacitive element and a manufacturing method of the same.

A semiconductor device according to one aspect of the invention has a capacitive element comprising a lower electrode, a capacitive insulation layer provided on the upper face of the lower electrode and comprising a dielectric layer, and an upper electrode provided on the upper face of the capacitive insulation layer on an insulation layer formed above a substrate, wherein an area of the lower electrode is larger than the area of the upper electrode, and the outer circumferential shape of the capacitive insulation layer is generally same as that of the lower electrode. In addition, here, the insulation layer formed above the substrate is directly formed on substrate, or the insulation layer is formed isolated by at least one or more wiring layers or other insulation layers formed on the substrate.

According to the above structure, because the capacitive insulation layer, which is on the lower electrode and in a region where the upper electrode is not provided on the upper side, is left without etching, damage by etching on the capacitive insulation layer below the end of the upper electrode can be reduced. For this reason, reduction in the insulation withstand voltage of the capacitive element can be suppressed.

Furthermore, according to the above structure, because the lower electrode and the capacitive insulation layer extend outwardly from the upper electrode and the upper electrode is not formed above the end of the capacitive insulation layer, the insulation withstand voltage of the capacitive element is not reduced even if the end of the capacitive insulation layer is damaged by etching when the capacitive insulation layer is formed.

Furthermore, according to the above structure, because the capacitive insulation layer can be used as a stopper layer for etching when a via hole leading onto the lower electrode is formed, etching depth can be easily controlled when the via hole leading onto the lower electrode is formed.

Furthermore, according to the above structure, because the outer circumferential shape of the lower electrode and the capacitive insulation layer are generally the same, a process of forming the capacitive insulation layer and a process of forming the lower electrode can share a part of the patterning process. As a result, the manufacturing process can be simplified.

The semiconductor device according to another aspect of the invention is the above described semiconductor device, in which the layer thickness of the capacitive insulation layer existing in a region where the upper electrode is not provided on the upper side is thinner than the layer thickness of the capacitive insulation layer existing in a region where the upper electrode is provided on the upper side.

According to the above structure, because the capacitive insulation layer formed above the lower electrode and existing in a region where the upper electrode is not provided on the upper side is not completely removing by etching, damage by etching on the capacitive insulation layer below the end of the upper electrode can be reduced in comparison with the damage in case that the capacitive insulation layer is completely removed. For this reason, the reduction in the insulation withstand voltage of the capacitive element can be suppressed.

Furthermore, according to the above structure, because the capacitive insulation layer formed above the lower electrode and existing in a region where the upper electrode is not provided on the upper side is thin, a parasitic capacitance generated between the lower electrode and a wiring located on a wiring layer in the upper layer and not conducted to the lower electrode, can be reduced.

The semiconductor device according to another aspect of the invention is the above described semiconductor device, in which a protective layer is coated on the capacitive insulation layer and in a region where the upper electrode is not provided on the upper side.

According to the above structure, because the protective layer isolates the capacitive insulation layer and the interlayer insulation layer deposited above the capacitive insulation layer, the chemical and dynamic influence of the interlayer insulation layer on the capacitive insulation layer can be prevented. As a result, reduction in the insulation withstand voltage of the capacitive element can be suppressed.

The semiconductor device according to another aspect of the invention is the above described semiconductor device, in which a wiring is formed on the insulation layer and a dielectric layer is coated on the wiring.

According to the above structure, because the dielectric layer functions as a stopper layer against etching when a via hole leading onto the wiring is formed, etching depth can be easily controlled when the via hole leading onto the wiring is formed.

The semiconductor device according to another aspect of the invention is the above described semiconductor device, in which the thickness of the dielectric layer coated on the wiring is thinner than that of the capacitive insulation layer in a region where the upper electrode is provided on the upper side.

According to the above structure, because the dielectric layer on the wiring is thin, the parasitic capacitance generated between the wiring and the other wirings located on the wiring layer in the upper layer and not conducted to the wiring can be reduced.

The semiconductor device according to another aspect of the invention is the above described semiconductor device, in which the lower electrode and the wiring are formed by patterning the same conductive layer.

According to the above structure, because the lower electrode of the capacitive element can be formed together with the wiring, the capacitive element can be formed in less number of processes.

A manufacturing method of a semiconductor device according to one aspect of the invention comprises depositing a first conductive layer on an insulation layer formed above a substrate, depositing a dielectric layer on the first conductive layer, depositing a second conductive layer on the dielectric layer, patterning the second conductive layer and forming the upper electrode of the capacitive element, and subsequently, patterning the first conductive layer and the dielectric layer generally in the same shape and forming a lower electrode and a capacitive insulation layer of the capacitive element. In addition, here, the insulation layer formed above the substrate comprises the case in which the insulation layer is directly formed on substrate, and also the case in which the insulation layer is formed isolated by at least one or more wiring layers or other insulation layers formed on the substrate.

According to the above manufacturing method, because the capacitive insulation layer which is on the lower electrode and in a region where the upper electrode is not provided on the upper side is not completely removing by etching, damage by etching on the capacitive insulation layer below the end of the upper electrode can be reduced in comparison with the damage in case that the capacitive insulation layer is completely removed. For this reason, the reduction in insulation withstand voltage of the capacitive element can be suppressed.

Furthermore, according to the above manufacturing method, because the lower electrode and the capacitive insulation layer extend outwardly from the upper electrode and the upper electrode is not formed above the end of the capacitive insulation layer, the insulation withstand voltage of the capacitive element is not reduced even if the end of the capacitive insulation layer is damaged by etching when the capacitive insulation layer is formed.

Furthermore, according to the above manufacturing method, because the capacitive insulation layer can function as a stopper layer for etching when a via hole leading onto the lower electrode is formed, etching depth can be easily controlled when the via hole leading onto the lower electrode is formed.

Furthermore, according to the above manufacturing method, because the shape of the outer circumferential shape of the lower electrode and the capacitive insulation layer are generally the same, a process of forming the capacitive insulation layer and a process of forming the lower electrode can share a part of the patterning process. As a result, the manufacturing process can be simplified.

Furthermore, according to the above manufacturing method, because the lower electrode, the dielectric layer and the upper electrode can be continuously deposited and there is no process such as etching in halfway, smoothness of each interface can be secured and at the same time no contamination occurs. As a result, reduction in the insulation withstand voltage of the capacitive element can be suppressed.

A manufacturing method of the semiconductor device according to another aspect of the invention comprises depositing a first conductive layer on an insulation layer formed above a substrate, depositing a dielectric layer on the first conductive layer, depositing a second conductive layer on the dielectric layer, patterning the second conductive layer and forming the upper electrode of the capacitive element, depositing protective layers on the dielectric layer and the upper electrode, and subsequently, patterning the first conductive layer, the dielectric layer and the protective layer generally in the same shape and forming the lower electrode of the capacitive element and the capacitive insulation layer.

According to the above manufacturing method, because the protective layer isolates the dielectric layer and an interlayer insulation layer is deposited above the dielectric layer, chemical and dynamic influence of the interlayer insulation layer on the capacitive insulation layer can be prevented. As a result, reduction in the insulation withstand voltage of the capacitive element can be suppressed.

The manufacturing method of the semiconductor device according to another aspect of the invention is the above described manufacturing method of the semiconductor device, comprising patterning the first conductive layer using the protective layer as a hard mask after patterning the protective layer.

According to the above manufacturing method, because the protective layer is also used as a hard mask, fine patterning can be performed without adding a process to separately form a hard mask different from the protective layer.

The manufacturing method of the semiconductor device according to another aspect of the invention is the above described manufacturing method of the semiconductor device in which the wiring is formed together with the lower electrode of the capacitive element by patterning the first conductive layer.

According to the above manufacturing method, because the lower electrode of the capacitive element can be formed together with the wiring, the capacitive element can be formed in a lower number of processes.

### BRIEF DESCRIPTION OF THE DRAWINGS

FIG. 1 is a cross sectional view showing a schematic structure of a semiconductor device according to a first embodiment of the invention.

FIGS. 2A-2C are cross sectional views showing three manufacturing processes of primary parts in a semiconductor device according to the first aspect of the invention.

FIGS. 3A & 3B are cross sectional views showing two manufacturing processes of primary parts in a semiconductor device according to the first embodiment of the invention.

FIGS. 4A-4C are sectional views showing manufacturing processes of primary parts in a semiconductor device according to the first embodiment of the invention, and showing processes following FIG. 3.

FIG. 5 is a sectional view showing manufacturing processes of primary parts in a semiconductor device according to this invention, and showing processes following FIGS. 4A-4B.

### DESCRIPTION OF THE PREFERRED EMBODIMENT

A first embodiment of this invention is described below based on the drawings. Further, the embodiment described below shall not limit the meaning of the invention described in claims. In addition, it is not limited that all of the configurations described below are essential as means to solve invention described in claims.

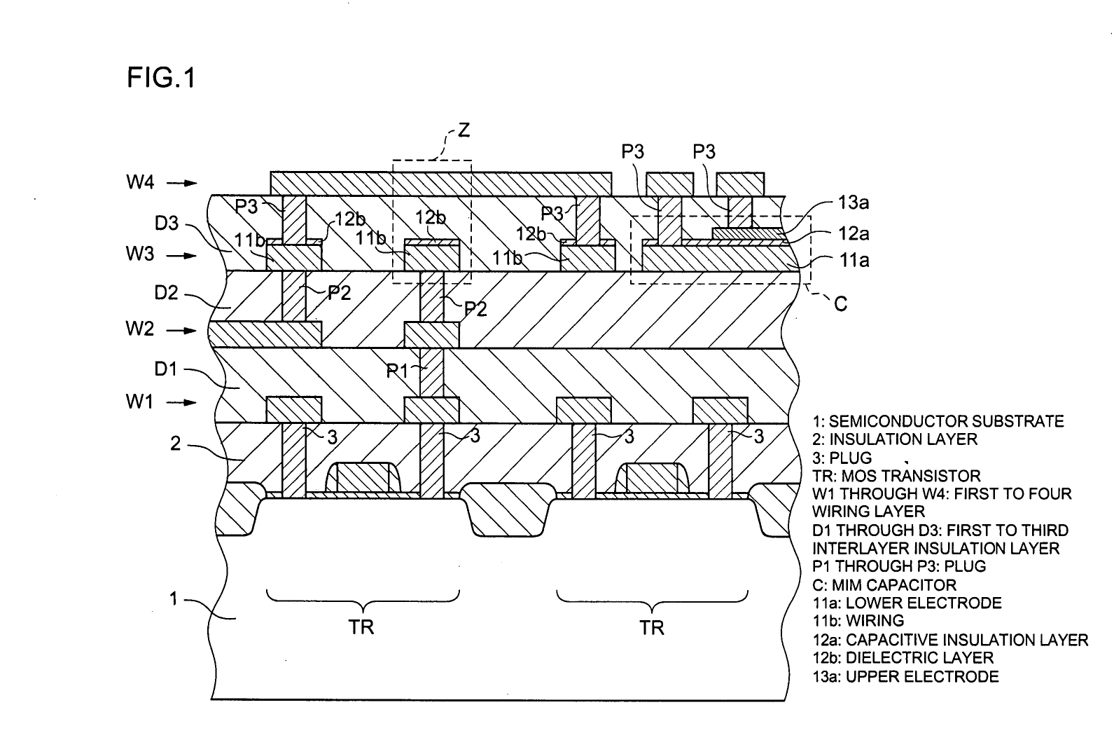

FIG. 1 is a cross-sectional view showing a schematic structure of the semiconductor device having a MIM capacitor as a capacitive element.

A plurality of MOS transistors TR are formed on a semiconductor substrate 1 as a substrate. Furthermore, an insulation layer 2 is formed on the semiconductor substrate 1 so as to cover the MOS transistors TR. Plugs 3 are formed to couple the MOS transistors TR and wirings or the like in the upper layers.

A multi-layered wiring structure having a plurality of wiring layers is formed on the insulation layer 2. As shown in FIG. 1, the multi-layered wiring structure of this embodiment has four wiring layers W1 through W4, and each of the wiring layer is insulated by interlayer insulation layers D1 through D3. Furthermore, plugs P1 through P3 are respectively formed in the first through third interlayer insulation layers D1 through D3, and conductions between different wiring layers can be made if necessary.

Furthermore, as shown with broken line in FIG. 1, a MIM capacitor C having a lower electrode 11a in the third wiring layer W3 is formed on the second interlayer insulation layer D2 as an insulation layer. The MIM capacitor C has the lower electrode 11a, a capacitive insulation layer 12a formed on the lower electrode 11a and composed of a dielectric layer, and an upper electrode 13a formed on the capacitive insulation layer 12a. The lower electrode 11a and the upper electrode 13a are coupled to the wiring layer in the upper layer (fourth wiring layer W4) by the plug 3.

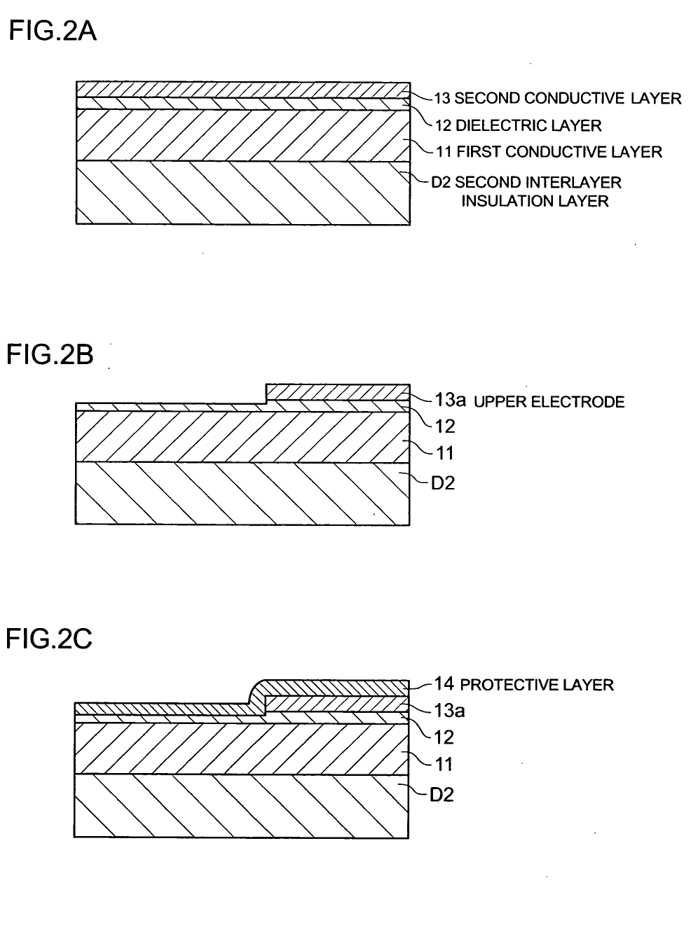

Next, taking as an example of a case that the MIM capacitor C is formed on the second interlayer insulation layer D2, the forming method is described using FIG. 2 through FIG. 5. In addition, for simplification, the drawing shows only the peripheral of the MIM capacitor C above the second interlayer insulation layer D2.

FIGS. 2A through 2C, FIGS. 3A through 3B, FIGS. 4A through 4C and FIG. 5 are cross-sectional views showing manufacturing processes of primary parts in the semiconductor device according to the first embodiment of the invention.

First, as shown in FIG. 2A, on the upper face of the second interlayer insulating layer D2 composed of silicon oxide layer, a first conductive layer 11, a dielectric layer 12 and a second conductive layer 13 forming the third wiring layer W3 as a conductive layer are continuously deposited. In this embodiment, the first conductive layer 11 is primarily composed of Al alloy layer, and on the front and back, a metallic layer composed of a plurality of layers having anti-reflection layer and barrier metal or the like constitutes the first conductive layer 11. These are deposited on the second interlayer insulation layer D2 by sputtering method. For the dielectric layer 12, a silicon nitride layer having a thickness of approximately 60 nm is used, and is deposited on the first conductive layer 11 by plasma CVD (Chemical Vapor Deposition) method. The second conductive layer 13 is primarily composed of Al alloy layer, and on the front and back, a metallic layer composed of a plurality of layers having anti-reflection layer and barrier metal or the like constitutes the second conductive layer 13. These are deposited on the dielectric layer 12 by sputtering method. In addition, on the faces of the first conductive layer 11 and second conductive layer 13 opposed to the dielectric layer 12, a TiN layer (not shown) is formed.

Next, as shown in FIG. 2B, the upper electrode 13a of the MIM capacitor C is formed by patterning the second conductive layer 13 by etching. Furthermore, the dielectric layer 12 below a region which is removed by etching of the second conductive layer 13 is also etched in the same pattern. However, in here, the dielectric layer 12 is not completely removed, and remains on the first conductive layer 11. In this embodiment, approximately half of the original layer thickness (approximately 30 nm) is left.

Next, as shown in FIG. 2C, a protective layer 14 composed of a silicon oxide layer in which a layer thickness is approximately 100 nm is formed on the upper faces of the upper electrode 13a and the exposed dielectric layer 12 by the plasma CVD method.

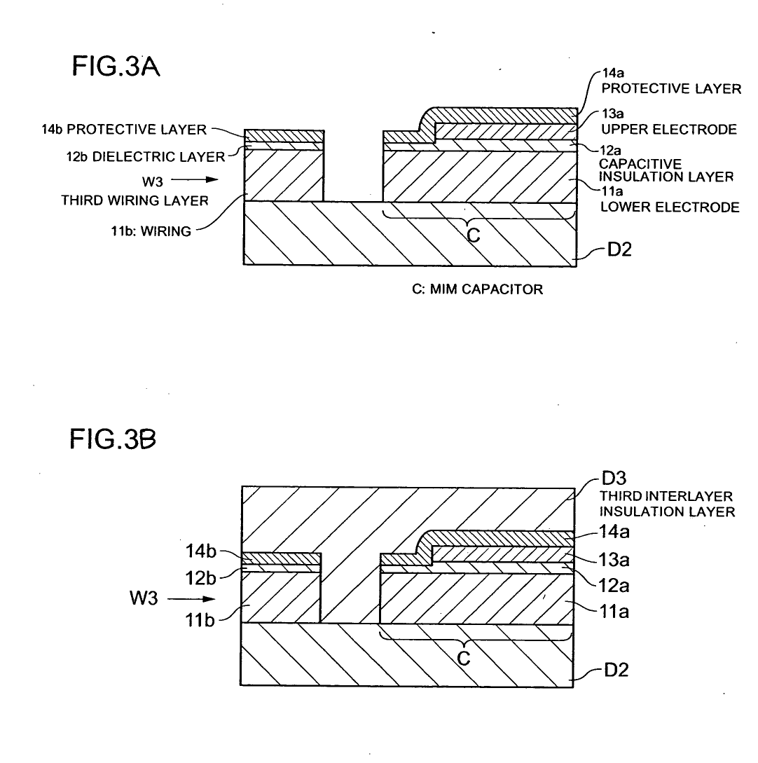

Next, the protective layer 14, the dielectric layer 12 and the first conductive layer 11 are patterned by etching. For detail, in conditions shown in FIG. 2C, a resist layer (not shown) is applied on the protective layer 14, and by exposing and developing this resist layer, a resist pattern (not shown) composed of the same pattern as that of the third wiring layer W3 is formed. Next, after using this resist pattern as a mask and patterning by etching the protective layer 14 and the dielectric layer 12, the resist pattern is removed. Subsequently, using the patterned protective layer 14 as a hard mask, the first conductive layer 11 is patterned by etching. By this, as shown in FIG. 3A, the lower electrode 11a of the MIM capacitor C and the wiring 11b are formed, and these constitute the third wiring layer W3.

Furthermore, the dielectric layer 12 of the upper layer of the lower electrode 11a is formed as a capacitive insulation layer 12a of the MIM capacitor C by patterning, and the MIM capacitor C is constituted by the lower electrode 11a, the capacitive insulation layer 12a and the upper electrode 13a. Here, because the capacitive insulation layer 12a and the lower electrode 11a are formed as described above, both have generally the same outer circumferential shapes. In addition, in this embodiment, because the layer thickness of the capacitive insulation layer 12a is approximately 60 nm, this MIM capacitor C obtains electrostatic capacitance of approximately 1 fF/μm².

Next, as shown in FIG. 3B, on the upper faces of the second interlayer insulation layer D2 and protective layers 14a and 14b, the third interlayer insulation layer D3 composed of FSG (F added SiO₂) and NSG (Non added SiO₂) is deposited by high density plasma CVD method, and the upper face thereof is polished and flattened by CMP (Chemical Mechanical Polishing) method.

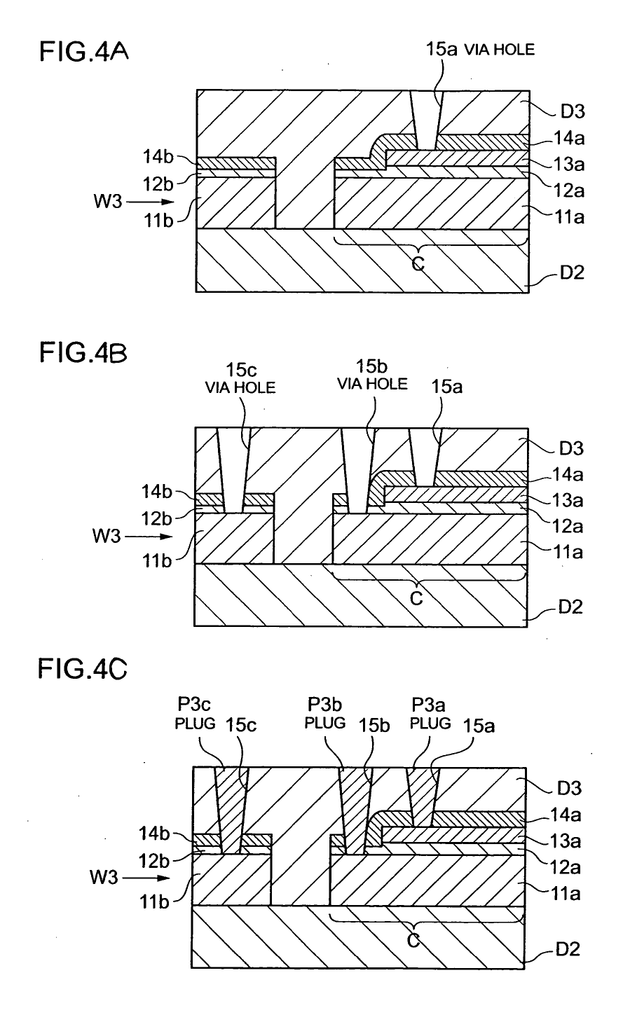

Next, as shown in FIG. 4A, the third interlayer insulation layer D3 and the protective layer 14a are etched, and a via hole 15a is formed on the upper electrode 13a. Then, as shown in FIG. 4B, the third interlayer insulation layer D3, the protective layer 14a and 14b, the dielectric layer (capacitive insulation layer) 12a and 12b are etched, and via holes 15b and 15c are formed on the lower electrode 11a and the wiring 11b respectively. In addition, in order to obtain stable coupling between the lower electrode 11a and the wiring 11b, and plugs formed subsequently in the via holes 15b and 15c, it is necessary to form the via holes 15b and 15c on the TiN layer of the uppermost layer of the lower electrode 11a and the wiring 11b composed of the first conductive layer 11. For this reason, when the via holes 15b and 15c are formed by etching, the etching depth must be controlled so that the TiN layer is not completely removed by overetching. Here, the dielectric layers (capacitive insulation layers) 12a and 12b on the lower electrode 11a and the wiring 11b function as a stopper layer for etching, and controlling the etching depth so that the via holes 15b and 15c are formed on the TiN layer.

Next, in the internal faces of the via holes 15a, 15b and 15c, a barrier metal (not shown) composed of TiN or the like is formed by sputtering method or CVD method. Then, as shown in FIG. 4C, in the via holes 15a, 15b and 15c, plugs P3a, P3b and P3c composed of tungsten are respectively embedded by CVD method, and the upper faces are polished and flattened by CMP method.

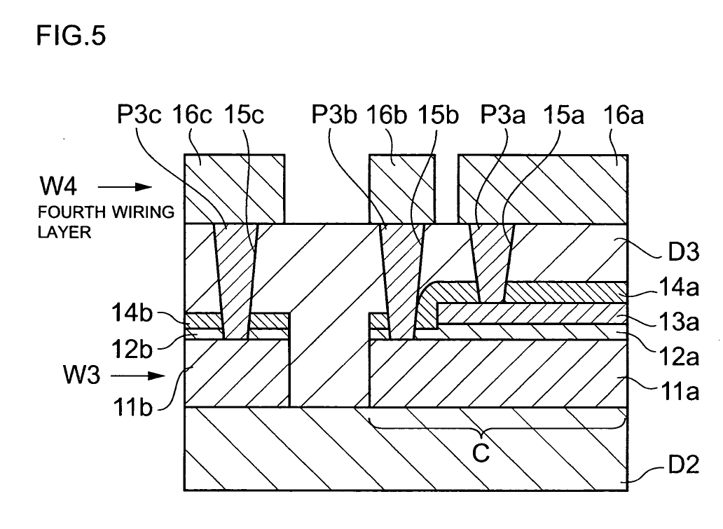

Next, on the third interlayer insulation layer D3, a conductive layer composed of a metal layer of Al alloy or the like is deposited by sputtering method, and then this is patterned by etching. By this, as shown in FIG. 5, the fourth wiring layer W4 is formed, and at the same time, the lower electrode 11a, the wiring 11b and the upper electrode 13a, and wirings 16b, 16c, 16a formed in the fourth wiring layer W4 are respectively coupled through plugs P3b, P3c and P3a.

In addition, the lower electrode 11a and the upper electrode 13a, viewed from the upper face, are generally rectangular shapes (not shown). The drawing shows only a cross section crossing one side among four sides of the rectangle, and here, because the via hole 15b is formed on the lower electrode 11a, the lower electrode 11a extends outwardly from the upper electrode 13a. On the other hand, via holes are not formed on the other three sides (not shown), but the lower electrode 11a is formed extending outwardly from the upper electrode 13a by at least 2 μm, or more, to be formed on any of the sides. And, even in those regions, the lower electrode 11a is coated with the capacitive insulation layer 12a, and further, the upper face is protected by a protective layer 14a.

As described above, the semiconductor device and the manufacturing method of the same of this invention have the following advantages.

(1) According to this embodiment, because the capacitive insulation layer 12a, which is on the lower electrode 11a of the MIM capacitor C, and in a region where the upper electrode 13a is not provided on the upper side is left without completely etching, damage by etching on the capacitive insulation layer 12a below the end of the upper electrode 13a can be reduced. For this reason, reduction in the insulation withstand voltage of the MIM capacitor can be suppressed.

(2) According to this embodiment, because the lower electrode 11a and the capacitive insulation layer 12a extend outwardly from the upper electrode 13a, and the upper electrode 13a is not formed above the end of the capacitive insulation layer 12a, the insulation withstand voltage of the MIM capacitor C is not reduced even if the end of the capacitive insulation layer 12a is damaged by etching when the capacitive insulation layer 12a is formed.

(3) According to this embodiment, because the outer circumferential shape of the lower electrode 11a and capacitive insulation layer 12a of the MIM capacitor C are the same, a process of forming the capacitive insulation layer 12a and a process of forming the lower electrode 11a can share a part of the patterning process (at least, exposing and developing processes). As a result, the manufacturing process can be simplified.

(4) According to this embodiment, on the lower electrode 11a of the MIM capacitor C, the capacitive insulation layer 12a exists even in a region where the upper electrode 13a is not provided on the upper side. Because this capacitive insulation layer 12a functions as a stopper layer for etching when a via hole is formed on the lower electrode 11a, etching depth can be easily controlled when the via hole on the lower electrode 11a is formed.

(5) According to this embodiment, because the capacitive insulation layer 12a formed on the lower electrode 11a of the MIM capacitor C and existing in a region where the upper electrode 13a is not provided on the upper side, and the dielectric layer 12b on the wiring 11b is thin, a parasitic capacitance (for example, a parasitic capacitance generated in a region Z shown with broken line in FIG. 1) generated between the other wirings located on the wiring layer in the upper layer and not conducted to the lower electrode an the wiring can be reduced.

(6) According to this embodiment, because the protective layer 14a is coated on the capacitive insulation layer 12a formed on the lower electrode 11a of the MIM capacitor C and existing in a region where the upper electrode 13a is not provided on the upper side, the protective layer 14 isolates the capacitive insulation layer 12a from the third interlayer insulation layer D3 deposited thereon. For this reason, reduction in mutual bonding capability by direct contact of the capacitive insulation layer 12a and FSG of the third interlayer insulation layer D3 can be prevented. In addition, chemical damage and dynamic stress by accumulation or the like of the fluorine released from the FSG of the third interlayer insulation layer D3 into an interface with the capacitive insulation layer 12a composed of the silicone nitride layer can be prevented. As a result, reduction in the insulation withstand voltage of the MIM capacitor can be suppressed.

(7) According to this embodiment, because the dielectric layer 12b exists on the wiring 11b, the dielectric layer 12b functions as a stopper layer for etching when a via hole leading onto the wiring 11 is formed. Accordingly, etching depth can be easily controlled when the via hole leading onto the wiring 11 is formed.

(8) According to this embodiment, because the lower electrode 11a of the MIM capacitor C is formed from the same conductive layer (first conductive layer 11) as that of the wiring 11b, the capacitive element can be formed in less number of processes.

(9) According to this embodiment, because the first conductive layer 11, the dielectric layer 12 and the second conductive layer 13 can be continuously deposited and there is no process such as etching halfway, smoothness of each interface can be secured and at the same time no contamination occurs. As a result, reduction in the insulation withstand voltage of the MIM capacitor can be suppressed.

(10) According to this embodiment, because the protective layer 14 is also used as a hard mask and the first conductive layer 11 is patterned, fine patterning can be performed without adding a process to separately form a hard mask different from the protective layer 14.

In addition, this invention is not limited to the configuration shown in the above embodiment, and can embody various changes. For example, in the above embodiment, the semiconductor device has four wiring layers W1 through W4, however, the number of the wiring layers may be more than or less than four. And, the MIM capacitor C formed on the second interlayer insulation layer D2 may be formed on any layer if on an insulation layer. However, in order to reduce the parasitic capacitance on the lower electrode 11a of the MIM capacitor and the silicon substrate 1, the MIM capacitor C is preferably formed on the second interlayer insulation layer D2, or on the insulation layer of a higher layer than the second interlayer insulation layer D2.

In addition, in the above embodiment, Al alloy layer is used for the first conductive layer 11 and the second conductive layer 13, however, other metallic layer such as Cu alloy layer may be used. In addition, the anti-reflection layer and barrier metal or the like constituting the front and bank layers of the first conductive layer 11 and the second conductive layer 13 may be omitted, while a metallic layer or the like for other purposes may be added. Similarly, for the materials and the layer thickness of the dielectric layer 12 (capacitive insulation layer 12a), the third interlayer insulation layer D3 and the protective layer 14, other than shown above in the embodiments can be used. However, the materials of the upper face of the first conductive layer 11 and the bottom face of the second conductive layer 13 contacting the dielectric layer 12 (capacitive insulation layer 12a) is preferably a combination which can prevent the mutual diffusion of atoms between the dielectric layer 12.

Furthermore, the method of depositing each of the layer and method of patterning are also not limited to the methods described in the above embodiments.

1. A semiconductor device having a capacitive element comprising:
a lower electrode;
a capacitive insulation layer provided on the upper face of the lower electrode, wherein said capacitive insulation layer is composed of a dielectric layer; and
an upper electrode provided on the upper face of the capacitive insulation layer, on an insulation layer formed above a substrate,
wherein,
an area of the lower electrode is larger than an area of the upper electrode, and an outer circumferential shape of the capacitive insulation layer is generally the same as an outer circumferential shape of the lower electrode.

2. The semiconductor device according to claim 1, wherein a first layer thickness of the capacitive insulation layer existing in a region where the upper electrode is not provided is thinner than a second layer thickness of the capacitive insulation layer existing in a region where the upper electrode is provided.

3. The semiconductor device according to claim 1, wherein a protective layer is coated on the capacitive insulation layer in a region where the upper electrode is not provided on the upper side.

4. The semiconductor device according to claim 1, wherein a wiring is formed on the insulation layer and a dielectric layer is coated on the wiring.

5. The semiconductor device according to claim 4, wherein the layer thickness of the dielectric layer coated on the wiring is thinner than the layer thickness of the capacitive insulation layer existing in a region where the upper electrode is provided on the upper side.

6. The semiconductor device according to claim 4, wherein the lower electrode and the wiring are formed by patterning the same conductive layer.

7. A method of manufacturing a semiconductor device, comprising:
depositing a first conductive layer on an insulation layer formed above a substrate;
depositing a dielectric layer on the first conductive layer;
depositing a second conductive layer on the dielectric layer;
patterning the second conductive layer and forming an upper electrode of a capacitive element; and subsequently,
patterning the first conductive layer and the dielectric layer generally in the same shape and forming a lower electrode and a capacitive insulation layer of the capacitive element.

8. A method of manufacturing a semiconductor device, comprising:
depositing a first conductive layer on an insulation layer formed above a substrate;
depositing a dielectric layer on the first conductive layer;
depositing a second conductive layer on the dielectric layer;
patterning the second conductive layer and forming an upper electrode of a capacitive element;
depositing a protective layer on the dielectric layer and the upper electrode; and subsequently,
patterning the first conductive layer, the dielectric layer and the protective layer generally in the same shape and forming a lower electrode and a capacitive insulation layer of the capacitive element.

9. The manufacturing method of a semiconductor device according to claim 8, wherein the protective layer is patterned and subsequently the first conductive layer is patterned by using the protective layer as a hard mask.

10. The manufacturing method of a semiconductor device according to claim 7, wherein a wiring is formed together with the lower electrode of the capacitive element by patterning the first conductive layer.

11. The semiconductor device according to claim 2 wherein a protective layer is coated on the capacitive insulation layer in a region where the upper electrode is not provided on the upper side.

12. The semiconductor device according to claim 2, wherein a wiring is formed on the insulation layer and dielectric layer is coated on the wiring.

13. The semiconductor device according to claim 3, wherein a wiring is formed on the insulation layer and dielectric layer is coated on the wiring.

14. The semiconductor device according to claim 5, wherein the lower electrode and the wiring are formed by patterning the same conductive layer.

15. The manufacturing method of a semiconductor device according to claim 8, wherein a wiring is formed together with the lower electrode of the capacitive element by patterning the first conductive layer.

16. The manufacturing method of a semiconductor device according to claim 9, wherein a wiring is formed together with the lower electrode of the capacitive element by patterning the first conductive layer.
